(19) United States
(12) Patent Application Publication
(10) Pub. No.: US 2015/0227165 A1
(43) Pub. Date: Aug. 13, 2015

(54) SUPPORTING DEVICE AND ELECTRONIC DEVICE HAVING THE SAME

(71) Applicants: Fu Tai Hua Industry (Shenzhen) Co., Ltd., Shenzhen (CN); HON HAI PRECISION INDUSTRY CO., LTD., New Taipei (TW)

(72) Inventor: JUN FENG, Shenzhen (CN)

(21) Appl. No.: 14/493,999

(22) Filed: Sep. 23, 2014

(30) Foreign Application Priority Data
Feb. 11, 2014 (CN) 201410047458.2

(51) Int. Cl. G06F 1/16; H05K 5/02; F16M 11/38

(52) U.S. Cl. CPC G06F 1/166; F16M 11/38; H05K 5/0234; H05K 5/0217

(57) ABSTRACT

A supporting device includes a casing, a fixing member, and a rotatable assembly. The casing includes a bottom surface. The fixing member is used to hold an electronic device. The rotatable assembly includes a rotatable portion and a connecting portion. The rotatable portion is rotatably connected to the casing. The connecting portion is connected to the fixing member, and can rotate with respect to the rotatable portion. The rotatable assembly is folded and received in the casing when the rotatable portion and the connecting portion are rotated to be parallel to the bottom surface. The rotatable assembly is further unfolded to adjust a height of the electronic device.

### FIELD

The present disclosure relates to supporting devices, and particularly to a supporting device capable of being folded and unfolded to adjust a height of an electronic device, and an electronic device having the supporting device.

### BACKGROUND

People often take their portable electronic devices (such as digital photo frames and tablet computers) with them when traveling. A stand for supporting an electronic device in an upright position on a desk or other flat surface is often used.

### BRIEF DESCRIPTION OF THE DRAWINGS

Many aspects of the embodiments with this disclosure can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views. The description is not to be considered as limiting the embodiments described herein.

FIG. 1 is an isometric view of an embodiment of a supporting device in a folded state.

FIG. 2 is similar to FIG. 1, but showing the supporting device in an unfolded state.

FIG. 3 is a partially disassembled, perspective view of the supporting device in FIG. 2.

FIG. 4 is an enlarged view of a circled portion in FIG. 3.

FIG. 5 is a cross-sectional view taken along line IV-IV of FIG. 3.

### DETAILED DESCRIPTION

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

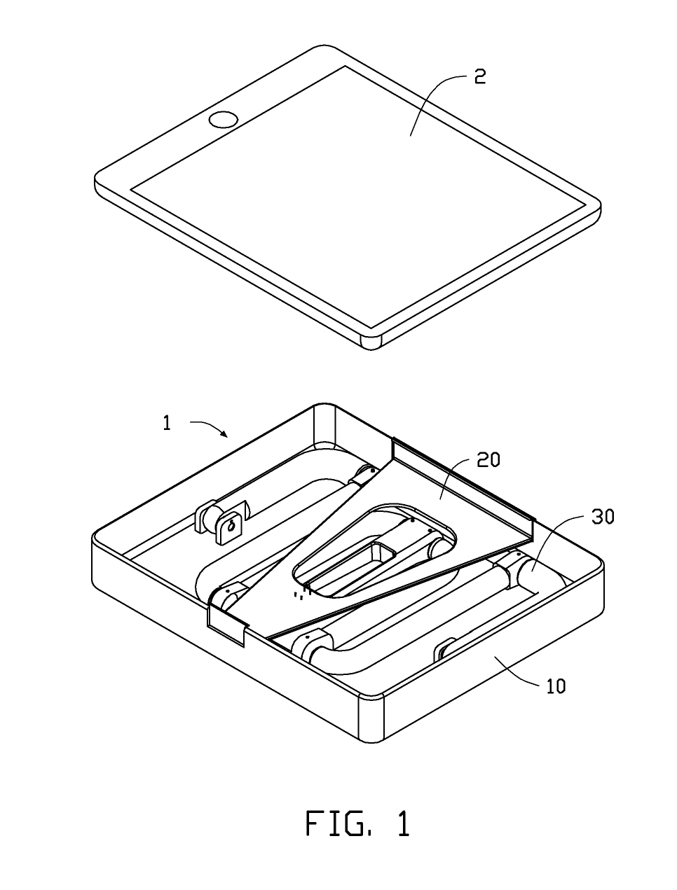

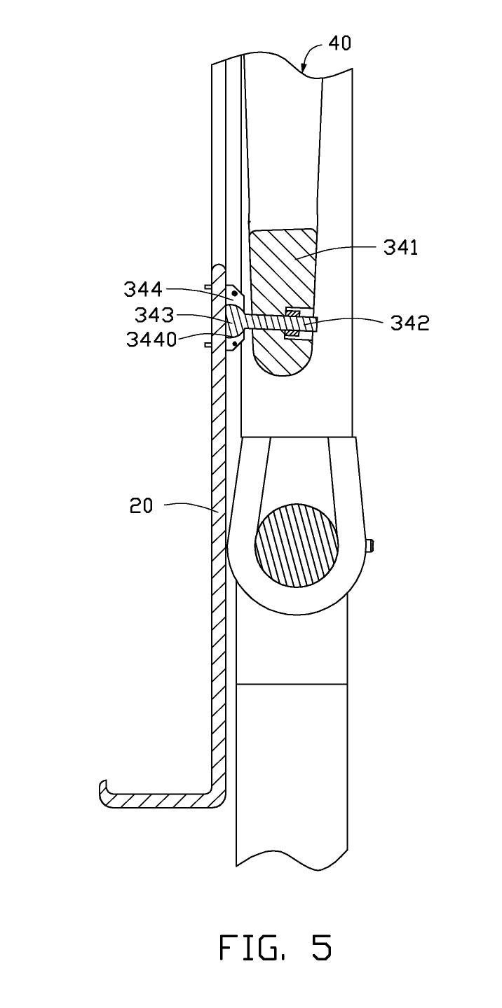

FIGS. 1-5 illustrate a supporting device 1 including a casing 10, a fixing member 20, and a rotatable assembly 30. The fixing member 20 can be connected to the rotatable assembly 30, and can be used to hold an electronic device 2 such as a tablet computer, a digital frame, or a cell phone. The rotatable assembly 30 can be unfolded or folded to adjust a height of the electronic device 2.

The casing 10 can be made of rubber or other flexible material, and can absorb external impact. The casing 10 can include a bottom surface 12 and four sidewalls 13 surrounding the bottom surface 12. Two first shafts 11 coaxial to each other can be attached to the bottom surface 12 and adjacent to two opposite sidewalls 13, respectively. Each of the two first shafts 11 can be substantially parallel to the bottom surface 12.

The fixing member 20 can include a first portion 21, a second portion 22, and a third portion 23. The first portion 21 and the second portion 22 can be connected to, and substantially perpendicular to, two opposite end portions of the third portion 23. The first portion 21, the second portion 22, and the third portion 23 can cooperatively bound a substantially “U”-shaped notch for retaining the electronic device 2 in the fixing member 20.

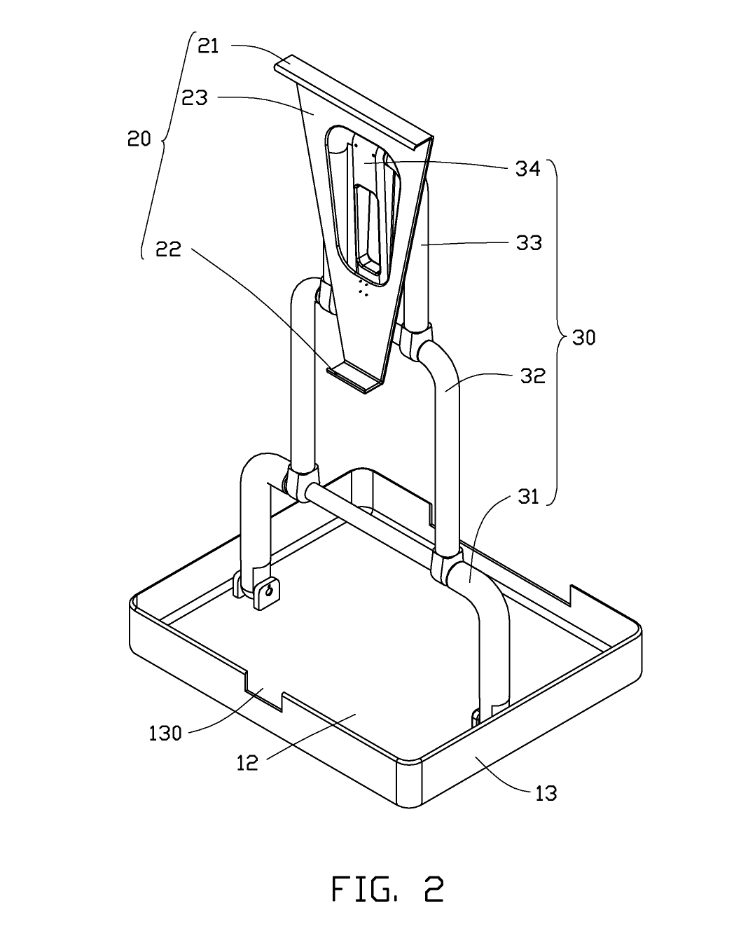

In at least one embodiment, the rotatable assembly 30 can include a first rotatable portion 31, a second rotatable portion 32, a third rotatable portion 33, and a connecting portion 34 rotatably connected to each other in order. The first rotatable portion 31 can be further rotatably connected to each of the two first shafts 11. The fixing member 20 can be fixedly or rotatably connected to the connecting portion 34. When the first rotatable portion 31, the second rotatable portion 32, the third rotatable portion 33, and the connecting portion 34 are rotated to be parallel to the bottom surface 12, the rotatable assembly 30 can be folded and received in the casing 10 (shown in FIG. 1). In at least one embodiment, two openings 130 can be defined in two opposite sidewalls 13 for receiving the first portion 21 and the second portion 22, respectively, when the rotatable assembly 30 is folded and received in the casing 10. When at least one of the first rotatable portion 31, the second rotatable portion 32, the third rotatable portion 33, and the connecting portion 34 is rotated and angled with the bottom surface 12, the rotatable assembly 30 can be unfolded, and a height of the rotatable assembly 30 can be changed, thereby adjusting the height of the electronic device 2 (shown in FIG. 2).

A number of the rotatable portions included in the rotatable assembly 30 can be changed according to need. In an alternative embodiment, the rotatable assembly 30 can only include the first rotatable portion 31, the second rotatable portion 32, and the connecting portion 34. In yet another alternative embodiment, the rotatable assembly 30 can only include the first rotatable portion 31 and the connecting portion 34.

Each of the first rotatable portion 31, the second rotatable portion 32, and the third rotatable portion 33 can be substantially “U”-shaped. Two end portions 310 of the first rotatable portion 31 can be rotatably connected to each of the two first shafts 11. Two end portions 320 of the second rotatable portion 32 can be rotatably connected to a center portion 311 of the first rotatable portion 31. Two end portions 330 of the third rotatable portion 33 can be rotatably connected to a center portion 321 of the second rotatable portion 32. A first end portion 340 of the connecting portion 34 can be rotatably connected to a center portion 331 of the third rotatable portion 33. Thus, the first rotatable portion 31, the second rotatable portion 32, the third rotatable portion 33, and the connecting portion 34 can be rotatably connected to each other in order.

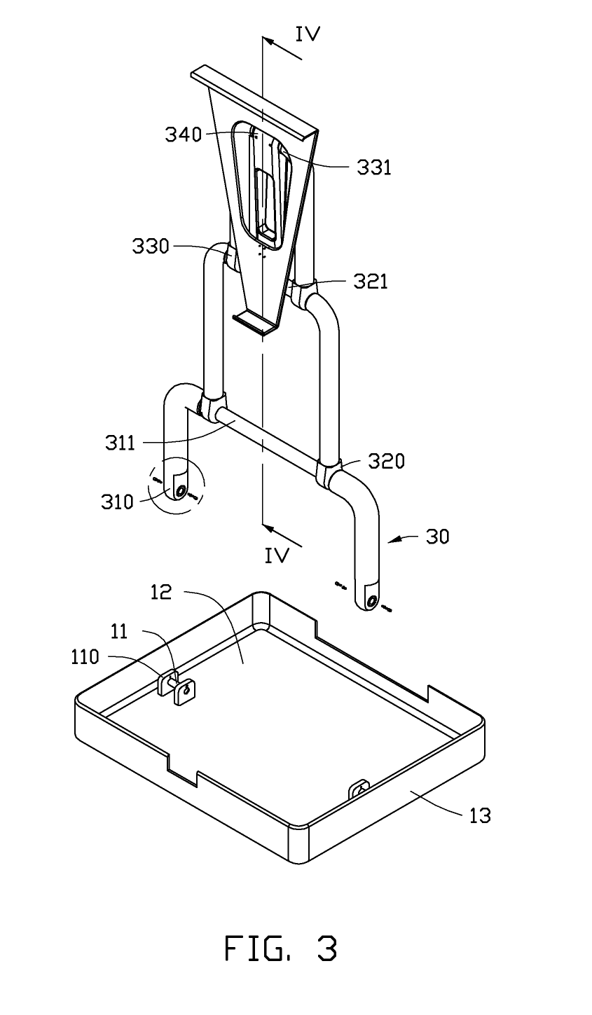

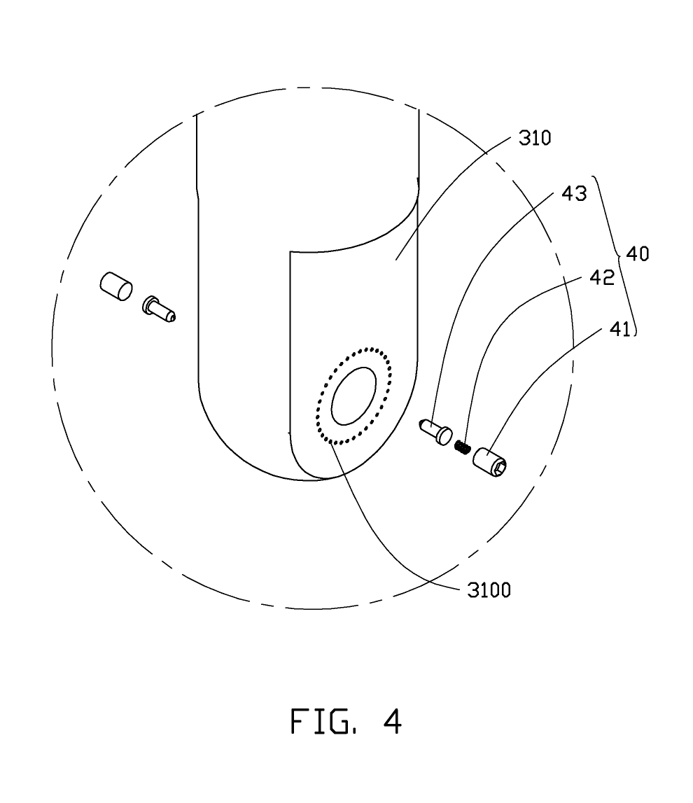

Referring to FIGS. 3-4, each shaft 11 can include a base 110 mounted to the bottom surface 12. Each end portion 310 of the first rotatable portion 31 can include at least one positioning member 40. The positioning member 40 can include a main body 41, an elastic element 42, and a positioning pin 43. The main body 41 can be secured to the base 110. The positioning pin 43 can be connected to the main body 41 via the elastic element 41. Each end portion 310 of the first rotatable portion 31 can define a number of positioning holes 3100 surrounding the corresponding first shaft 11. The elastic element 42 can be a coil spring, and can be elastically compressed when the first rotatable portion 31 is rotated about the first shafts 11, and rebound when the positioning pin 43 is inserted into one of the number of positioning holes 3100. Thus, the first rotatable portion 31 can be retained at a desired position with respect to each of the two first shafts 11. In at least one embodiment, the positioning member 40 can be omitted, and the first rotatable portion 31 can be retained at the desired position by friction between the first rotatable portion 31 and each of the two first shafts 11.

The second rotatable portion 32 can also include at least one positioning member (not shown) configured to allow the second rotatable portion 32 to be retained at a desired position with respect to the first rotatable portion 31. The positioning member of the second rotatable portion 32 can have the same features as the positioning member 40 of the first rotatable portion 31. The third rotatable portion 33 and the connecting portion 34 can also include at least one positioning member.

In at least one embodiment, the connecting portion 34 can further include a second end portion 341 opposite to the first end portion 340. A second shaft 342 substantially perpendicular to each of the two first shafts 11 can be connected to the second end portion 341. The fixing member 20 can be rotatably connected to the connecting portion 34 via the second shaft 342, and can be rotated about the second shaft 342. Thus, the electronic device 2 can be rotated with the fixing member 20 to a desired orientation, such as a portrait or landscape orientation. In at least one embodiment, the second shaft 342 can include a substantially spherical head portion 343. A connecting plate 344 can be connected to the fixing member 20, and can define a groove 3440 to receive the head portion 343. The head portion 343 can rotate in the groove 3440, thus allowing the fixing member 20 to rotate about the second shaft 342.

It is to be understood that, even though information and advantages of the present embodiments have been set forth in the foregoing description, together with details of the structures and functions of the present embodiments, the disclosure is illustrative only. Changes may be made in detail, including in matters of shape, size, and arrangement of parts within the principles of the present embodiments to the full extent indicated by the plain meaning of the terms in which the appended claims are expressed.

What is claimed is:

1. A supporting device comprising:
a casing comprising a bottom surface;
a fixing member for holding an electronic device; and
a rotatable assembly including:
a first rotatable portion rotatably connected to the casing; and
a connecting portion connected to the fixing member and able to be rotated with respect to the first rotatable portion, the rotatable assembly being folded and received in the casing when the first rotatable portion and the connecting portion are rotated to be parallel to the bottom surface, and being unfolded to adjust a height of the electronic device when at least one of the first rotatable portion and the connecting portion is rotated to be angled with the bottom surface.

2. The supporting device of claim 1, wherein the fixing member comprises a first portion, a second portion, and a third portion, the first portion and the second portion are connected to two opposite end portions of the third portion, the first portion, the second portion, and the third portion cooperatively bound a “U”-shaped notch for retaining the electronic device in the fixing member.

3. The supporting device of claim 2, wherein the casing further comprises four sidewalls surrounding the bottom surface, and two openings are defined in two opposite sidewalls for receiving the first portion and the second portions, respectively, when the rotatable assembly is folded and received in the casing.

4. The supporting device of claim 1, wherein the casing is made of a flexible material.

5. The supporting device of claim 1, wherein two first shafts coaxial to each other are attached to the bottom surface, each of the two first shafts is parallel to the bottom surface, and the first rotatable portion is rotatably connected to the each of the two first shafts.

6. The supporting device of claim 5, wherein the rotatable assembly further comprises a second rotatable portion and a third rotatable portion, the first rotatable portion, the second rotatable portion, the third rotatable portion, and the connecting portion are rotatably connected to each other in order, when the first rotatable portion, the second rotatable portion, the third rotatable portion, and the connecting portion are rotated to be parallel to the bottom surface, the rotatable assembly is folded and received in the casing, when at least one of the first rotatable portion, the second rotatable portion, the third rotatable portion, and the connecting portion is rotated and angled with the bottom surface, the rotatable assembly is unfolded to adjust a height of the electronic device.

7. The supporting device of claim 6, wherein each of the first rotatable portion, the second rotatable portion, and the third rotatable portion is substantially “U”-shaped, two end portions of the first rotatable portion are rotatably connected to each of the two first shafts, two end portions of the second rotatable portion are rotatably connected to a center portion of the first rotatable portion, two end portions of the third rotatable portion are rotatably connected to a center portion of the second rotatable portion, and a first end portion of the connecting portion is rotatably connected to a center portion of the third rotatable portion.

8. The supporting device of claim 7, wherein each end portion of the first rotatable portion comprises at least one positioning member, the positioning member comprises a main body, an elastic element, and a positioning pin, the main body is secured to the corresponding shaft, the positioning pin is connected to the main body via the elastic element, each end portion of the first rotatable portion further defines a plurality of positioning holes surrounding the corresponding first shaft, the elastic element is elastically compressed when the first rotatable portion is rotated about the first shafts, and rebounds when the positioning pin inserts into one of the plurality of positioning hole, thereby retaining the first rotatable portion at a desired position with respect to the first shafts.

9. The supporting device of claim 8, wherein the first rotatable portion is retained at the desired position by friction between the first rotatable portion and the first shafts.

10. The supporting device of claim 7, wherein the connecting portion further comprises a second end portion opposite to the first end portion, a second shaft substantially perpendicular to the first shaft is connected to the second end portion, the fixing member is rotatably connected to the connecting portion via the second shaft, thereby allowing the electronic device to rotate with the fixing member.

11. The supporting device of claim 10, wherein the second shaft comprises a substantially spherical head portion, a connecting plate is connected to the fixing member, and defines a groove to receive the head portion, the head portion is rotated in the groove, thereby allowing the fixing member to rotate about the second shaft.

12. An electronic device having a supporting device, the supporting device comprising:
a casing comprising a bottom surface;
a fixing member for holding the electronic device; and
a rotatable assembly including:
a first rotatable portion rotatably connected to the casing; and
a connecting portion connected to the fixing member and able to be rotated with respect to the first rotatable portion, the rotatable assembly being folded and received in the casing when the first rotatable portion and the connecting portion are rotated to be parallel to the bottom surface, and being unfolded to adjust a height of the electronic device when at least one of the first rotatable portion and the connecting portion is rotated to be angled with the bottom surface.

13. The electronic device of claim 12, wherein the fixing member comprises a first portion, a second portion, and a third portion, the first portion and the second portion are connected to two opposite end portions of the third portion, the first portion, the second portion, and the third portion cooperatively bound a “U”-shaped notch for retaining the electronic device in the fixing member.

14. The electronic device of claim 12, wherein the casing is made of a flexible material.

15. The electronic device of claim 12, wherein two first shafts coaxial to each other are attached to the bottom surface, each of the two first shafts is parallel to the bottom surface, and the first rotatable portion is rotatably connected to each of the two first shafts.

16. The electronic device of claim 15, wherein the rotatable assembly further comprises a second rotatable portion and a third rotatable portion, the first rotatable portion, the second rotatable portion, the third rotatable portion, and the connecting portion are rotatably connected to each other in order, when the first rotatable portion, the second rotatable portion, the third rotatable portion, and the connecting portion are rotated to be parallel to the bottom surface, the rotatable assembly is folded and received in the casing, when at least one of the first rotatable portion, the second rotatable portion, the third rotatable portion, and the connecting portion is rotated and angled with the bottom surface, the rotatable assembly is unfolded to adjust a height of the electronic device.

17. The electronic device of claim 16, wherein each of the first rotatable portion, the second rotatable portion, and the third rotatable portion is substantially “U”-shaped, two end portions of the first rotatable portion are rotatably connected to the first shafts, two end portions of the second rotatable portion are rotatably connected to a center portion of the first rotatable portion, two end portions of the third rotatable portion are rotatably connected to a center portion of the second rotatable portion, and a first end portion of the connecting portion is rotatably connected to a center portion of the third rotatable portion.

18. The electronic device of claim 17, wherein each end portion of the first rotatable portion comprises at least one positioning member, the positioning member comprises a main body, an elastic element, and a positioning pin, the main body is secured to the corresponding shaft, the positioning pin is connected to the main body via the elastic element, each end portion of the first rotatable portion further defines a plurality of positioning holes surrounding the corresponding first shaft, the elastic element is elastically compressed when the first rotatable portion is rotated about the first shafts, and rebounds when the positioning pin inserts into one of the plurality of positioning hole, thereby retaining the first rotatable portion at a desired position with respect to the first shafts.

19. The electronic device of claim 18, wherein the first rotatable portion is retained at the desired position by friction between the first rotatable portion and the first shafts.

20. The electronic device of claim 17, wherein the connecting portion further comprises a second end portion opposite to the first end portion, a second shaft substantially perpendicular to the first shaft is connected to the second end portion, the fixing member is rotatably connected to the connecting portion via the second shaft, thereby allowing the electronic device to rotate with the fixing member.
